(19) United States
(12) Patent Application Publication
(10) Pub. No.: US 2021/0298163 A1
(43) Pub. Date: Sep. 23, 2021

(54) ELECTRONIC APPARATUS AND STACKING CONNECTOR

(71) Applicant: Kioxia Corporation, Tokyo (JP)

(72) Inventor: Yoshiaki YOSHIHARA, Yokohama Kanagawa (JP)

(73) Assignee: Kioxia Corporation, Tokyo (JP)

(21) Appl. No.: 17/184,145

(22) Filed: Feb. 24, 2021

(30) Foreign Application Priority Data
Mar. 17, 2020 (JP) 2020-046727

(51) Int. Cl. H05K 1/02; H05K 1/14; H05K 7/20; H01R 12/71; H05K 1/18

(52) U.S. Cl. CPC H05K 1/0203; H05K 1/144; H05K 7/20009; G06F 1/20; H05K 1/181; H05K 2201/10159; H01R 12/712

(57) ABSTRACT

An electronic apparatus includes: a casing; a first board that is provided in the casing that includes a first surface and a first connector, the first connector provided on the first surface; and a second board that is provided in the casing and including a second surface facing the first surface and a second connector provided on the second surface. The first connector and the second connector are connected to each other. The first connector and the second connector connected to each other include a ventilation passage.

### CROSS-REFERENCE TO RELATED APPLICATION(S)

This application is based upon and claims the benefit of priority from Japanese Patent Application No. 2020-046727, filed Mar. 17, 2020, the entire contents of which are incorporated herein by reference.

### FIELD

Embodiments described herein relate generally to an electronic apparatus and a stacking connector.

### BACKGROUND

An electronic apparatus is configured with a casing and an electronic component provided in the casing. The electronic component generates heat while the electronic apparatus is operating. As a result, a temperature of the electronic component increases.

### DESCRIPTION OF THE DRAWINGS

FIG. 1 is a perspective view of an electronic apparatus according to at least one embodiment.

FIG. 2 is a cross-sectional view taken along a line 2-2 of FIG. 1.

FIGS. 3A and 3B are plan views of a first PCB.

FIGS. 4A and 4B are plan views of a second PCB.

FIG. 5 is a perspective view showing a modification of the second PCB.

FIG. 6 is a plan view of a first base.

FIG. 7 is a cross-sectional view taken along a line 7-7 of FIG. 6.

FIG. 8 is a plan view showing a base, a cover, the first PCB, and the second PCB seen from above a casing.

FIG. 9 is a cross-sectional view taken along a line 9-9 of FIG. 8.

FIG. 10 is a plan view of a stacking connector according to at least one embodiment.

FIG. 11 is a cross-sectional view taken along a line 11-11 of FIG. 10.

FIG. 12 is a perspective view of the stacking connector according to at least one embodiment.

FIG. 13 is a perspective view for explaining effects of the electronic apparatus according to at least one embodiment.

FIG. 14 is a perspective view illustrating a modification of the electronic apparatus according to at least one embodiment.

FIG. 15 is a perspective view illustrating another modification of the electronic apparatus according to at least one embodiment.

FIG. 16 is a plan view illustrating yet another modification of the electronic apparatus according to at least one embodiment.

### DETAILED DESCRIPTION

At least one embodiment provides an electronic apparatus and a stacking connector capable of preventing an increase in temperature of an electronic component in a casing.

In general, according to at least one embodiment, an electronic apparatus includes: a casing; a first board that is provided in the casing, the first board including a first surface and a first connector provided on the first surface; and a second board provided in the casing, the second board including a second surface facing the first surface and a second connector provided on the second surface. The first connector and the second connector are connected to each other. The first connector and the second connector connected to each other include one or more ventilation passages.

Embodiments will be described hereinafter with reference to the drawings. The drawings are either schematic or conceptual and not necessarily identical to actual ones. Furthermore, in the drawings, the same reference sign denotes the same or corresponding parts and repetitive description is often omitted. Moreover, for brevity, even the same or corresponding part is not often denoted by a reference sign.

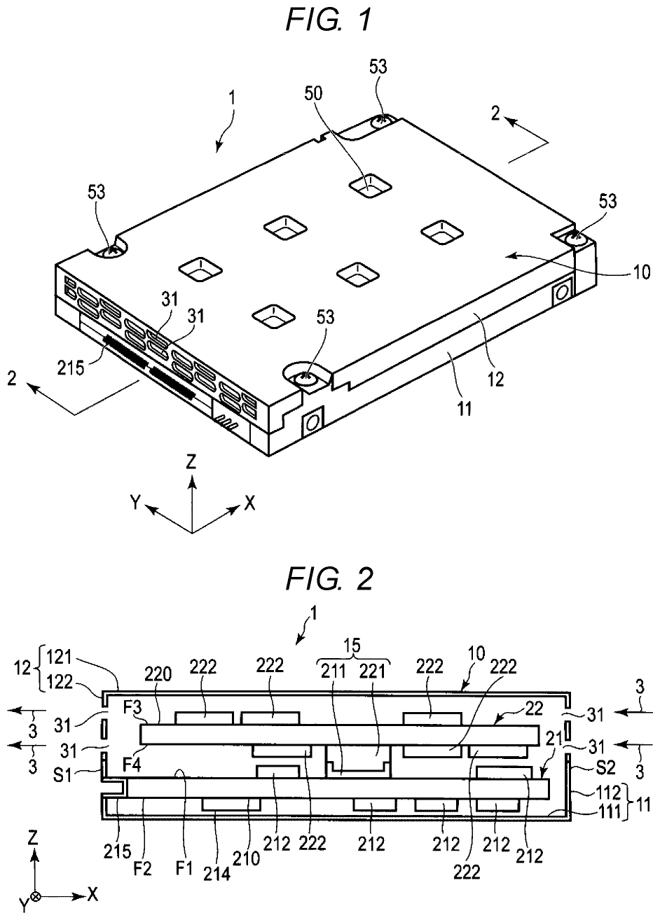

FIG. 1 is a perspective view of an electronic apparatus according to at least one embodiment. FIG. 2 is a cross-sectional view taken along a line 2-2 of FIG. 1.

In at least one embodiment, the electronic apparatus 1 is an SSD (Solid State Drive). As shown in FIG. 1, the electronic apparatus 1 has a rectangular parallelepiped appearance. Furthermore, as shown in FIG. 2, the electronic apparatus 1 includes a casing 10, a first PCB (printed circuit board) 21 provided in the casing 10, and a second PCB 22 provided in the casing 10 to be apart from the first PCB 21.

The casing 10 includes abase 11 and a cover 12 assembled with this base 11. The base 11 and the cover 12 configure the casing 10 that has a hollow rectangular parallelepiped shape. The base 11 and the cover 12 each have a rectangular planar shape. As shown in FIG. 1, the cover 12 may be attached to the base 11 by a plurality of screws 53.

It is noted that X, Y, and Z indicate three axes orthogonal to one another in FIG. 1. An X-axis direction is a longitudinal direction of the cover 12 or the base 11. A Y-axis direction is a short-length direction of the cover 12 or the base 11. A Z-axis direction is a thickness direction of the casing 10. It is also defined in the following description that a relative positional relationship among elements arranged in the Z-axis direction is a vertically-structured relationship.

As shown in FIG. 2, the base 11 includes a first base 111 and a second base 112. The first base 111 configures a lower wall (bottom plate) of the casing 10. The first base 111 has a rectangular planar shape. The second base 112 is provided in a peripheral portion of the first base 111 and configures part of a peripheral wall (side wall) of the casing 10.

The cover 12 includes a first cover 121 and a second cover 122. The first cover 121 configures an upper wall (top plate) of the casing 10. The first cover 121 has a rectangular planar shape. As shown in FIG. 1, recess portions 50 are provided in the first cover 121. The recess portions 50 can be used as heat dissipation paths in the casing 10. The second cover 122 is provided in a peripheral portion of the first cover 121 and configures part of the peripheral wall (side wall) of the casing 10.

As shown in FIG. 2, the second cover 122 has a first surface S1 and a second surface S2. The first surface S1 and the second surface S2 are parallel to a Y-Z plane specified by three axes of the X, Y, and Z-axes. A plurality of cooling ventilation holes 31 for conducting air inside and outside of the casing 10 are provided in the first surface S1 and the second surface S2. In at least one embodiment, it is assumed that air 3 enters from a ventilation holes 31 in the second surface S2 and exits from a ventilation holes 31 in the first surface S1.

The air 3 is generated using a cooling fan (not shown) or the like while the electronic apparatus 1 is operating. The fan is provided in, for example, an apparatus (for example, an enterprise-oriented server) in which the electronic apparatus 1 that is the SSD is incorporated.

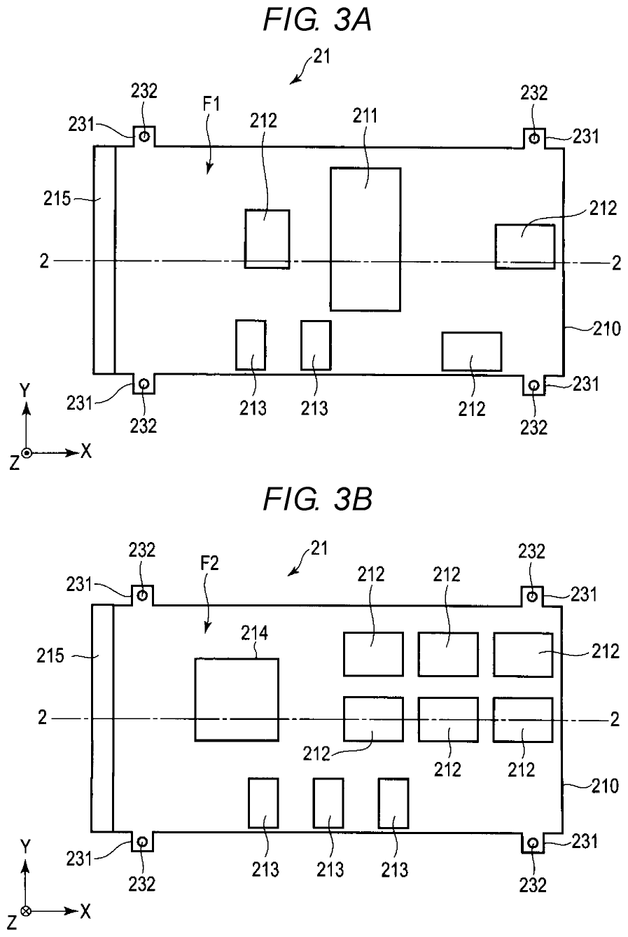

FIG. 3A is a plan view of an upper surface F1 of the first PCB 21 of FIG. 2. FIG. 3B is a plan view of a lower surface F2 of the first PCB 21 of FIG. 2 and is a perspective view of the first PCB 21 from the upper surface F1 side of the first PCB 21. The lower surface F2 is a surface that faces the first base 111 of FIG. 2 and that is an opposite surface to the upper surface F1. Furthermore, cross-sectional views taken along a line 2-2 of FIGS. 3A and 3B correspond to a cross-sectional view of the first PCB 21 in FIG. 2.

As shown in FIGS. 3A and 3B, the first PCB 21 includes a first printed wiring board 210 and a plurality of electronic components 211, 212, 213, and 214 provided on this first printed wiring board 210.

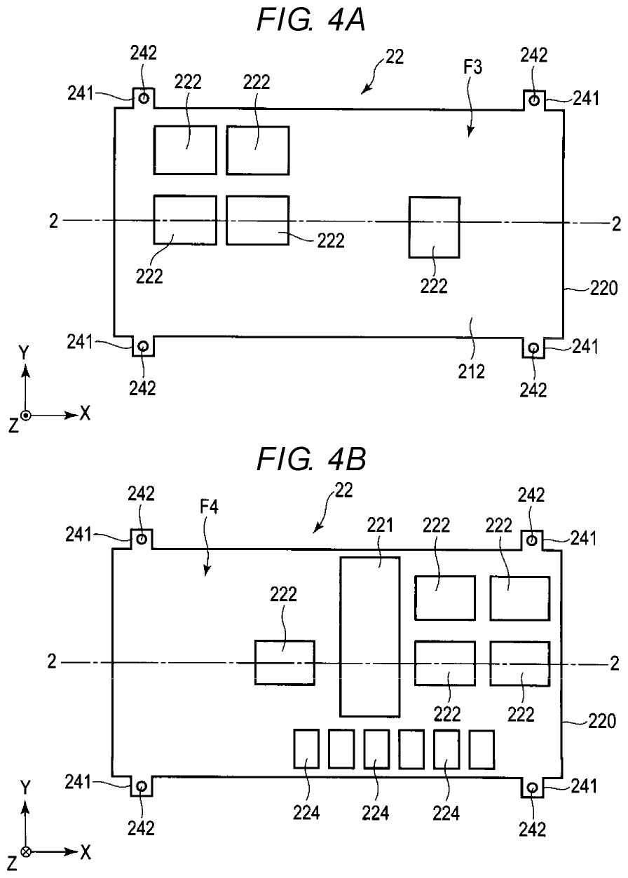

Specifically, as shown in FIG. 3A, the electronic components such as a first connector 211, a plurality of NAND flash memory 212, a plurality of DRAMs (Dynamic Random Access Memories) 213, and a connector (third connector) 215 are provided on the upper surface F1. It is noted that relatively small components such as resistors are not shown for simplicity (which applies to FIGS. 3B, 4A, and 4B).

In FIG. 3A, the NAND flash memory 212, the first connector 211, a controller 214, and the NAND flash memory 212 are placed (mounted) along a chain line 2-2 starting from the left. A plurality of DRAMs 213 and the NAND flash memory 212 are placed along the X-axis starting from the left below the chain line 2-2 with respect to the Y-axis.

The first connector 211 is a male connector out of two connectors that configure a stacking connector (also referred to as “board-to-board connector”) 15 depicted in FIG. 2. The stacking connector 15 connects the first PCB 21 to the second PCB 22. Each NAND flash memory 212 is a nonvolatile semiconductor memory that is a kind of nonvolatile memory. A nonvolatile magnetic memory which is, for example, an MRAM (magnetic random access memory) may be used as an alternative to the nonvolatile semiconductor memory. In the present embodiment, the controller 214 controls the NAND flash memories 212 on the first PCB 21 and NAND flash memories 222 on the second PCB 22 to be described later (FIGS. 4A and 4B).

One end (a first end) of a first signal line (not shown) for transmitting a first control signal for controlling the NAND flash memories 212 is connected to the controller 214, and the other end (a second end) of the first signal line is connected to the NAND flash memories 212. In addition, one end (a first end) of a second signal line (not shown) for transmitting a second control signal for controlling the NAND flash memories 222 is connected to the controller 214, and the other end (a second end) of this second signal line is connected to the NAND flash memories 222 via the stacking connector 15.

Moreover, as shown in FIG. 3B, electronic components such as a plurality of NAND flash memories 212, a plurality of DRAMs 213, the controller 214, and a connector (third connector) 215 are provided on the lower surface F2. The controller 214 is placed (mounted) between the connector 215 and the stacking connector 15 on the lower surface F2.

In FIG. 3B, a plurality of NAND flash memories 212 are arranged along the chain line 2-2. A plurality of NAND flash memories 212 are placed along the X-axis above the chain line 2-2 with respect to the Y-axis. A plurality of DRAMS 213 are placed (mounted) along the X-axis below the chain line 2-2 with respect to the Y-axis.

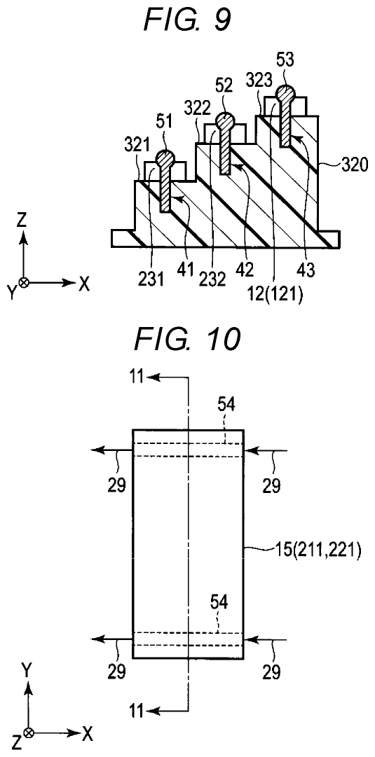

As shown in FIGS. 3A and 3B, protruding portions 231 are provided in four corners of the first printed wiring board 210, respectively. The protruding portions 231 protrude along the Y-axis. A screw through-hole 232 is provided in each of the protruding portions 231. A screw 51 penetrates through the through-hole 232 as shown in FIGS. 8 and 9 to be described later.

Moreover, as shown in FIGS. 1 and 2, the connector (third connector) 215 that can be electrically connected to an external apparatus (not shown) such as a host device is provided in one end portion of the first PCB 21 in the X-axis direction. As the connector 215, a connector compliant with a standard such as PCIe (registered trademark) (Peripheral Component Interconnect express) or SAS (Serial Attached Small Computer System Interface) is used.

FIG. 4A is a plan view of an upper surface F3 of the second PCB 22 of FIG. 2. FIG. 4B is a plan view of a lower surface F4 of the second PCB 22 of FIG. 2 and is a perspective view of the second PCB 22 from the upper surface F3 side of the second PCB 22. The upper surface F3 is a surface that faces the first cover 121 of FIG. 2 and that is an opposite surface to the lower surface F4. Furthermore, cross-sectional views taken along a line 2-2 of FIGS. 4A and 4B correspond to a cross-sectional view of the second PCB 22 in FIG. 2.

As shown in FIGS. 4A and 4B, the second PCB 22 includes a second printed wiring board 220 and a plurality of electronic components 221, 222, 223, and 224 provided on this second printed wiring board 220.

Specifically, as shown in FIG. 4A, a plurality of NAND flash memories 222 are placed (mounted) on the upper surface F3. Each of the NAND flash memories 222 on the second PCB 22 has a memory capacity either identical to, or different from, a memory capacity of each of the NAND flash memories 212 on the first PCB 21.

In FIG. 4A, a plurality of NAND flash memories 222 are placed along the chain line 2-2. A plurality of NAND flash memories 222 are placed along the X-axis above the chain line 2-2 with respect to the Y-axis.

Moreover, as shown in FIG. 4B, electronic components such as the second connector 221, a plurality of NAND flash memories 222, and a plurality of capacitors 224 are provided on the lower surface F4.

In FIG. 4B, a plurality of NAND flash memories 222, the second connector 221, and a plurality of NAND flash memories 222, are placed along a chain line 2-2 starting from the left on the lower surface F4. A plurality of NAND flash memories 222 are placed along the X-axis above the chain line 2-2 with respect to the Y-axis and on the right of the second connector 221. A plurality of capacitors 224 are placed (mounted) along the X-axis below the chain line 2-2 with respect to the Y-axis.

The second connector 221 may be a female connector out of the two connectors that configure the stacking connector 15 shown in FIG. 2. It is noted that the second connector 221 and the first connector 211 may be conversely a male connector and a female connector, respectively. As shown in FIGS. 4A and 4B, protruding portions 241 are provided in four corners of the second printed wiring board 220, respectively. The protruding portions 241 protrude along the Y-axis. A screw through-hole 242 is provided in each of the protruding portions 241. A screw 52 penetrates through the through-hole 242 as shown in FIGS. 8 and 9 to be described later.

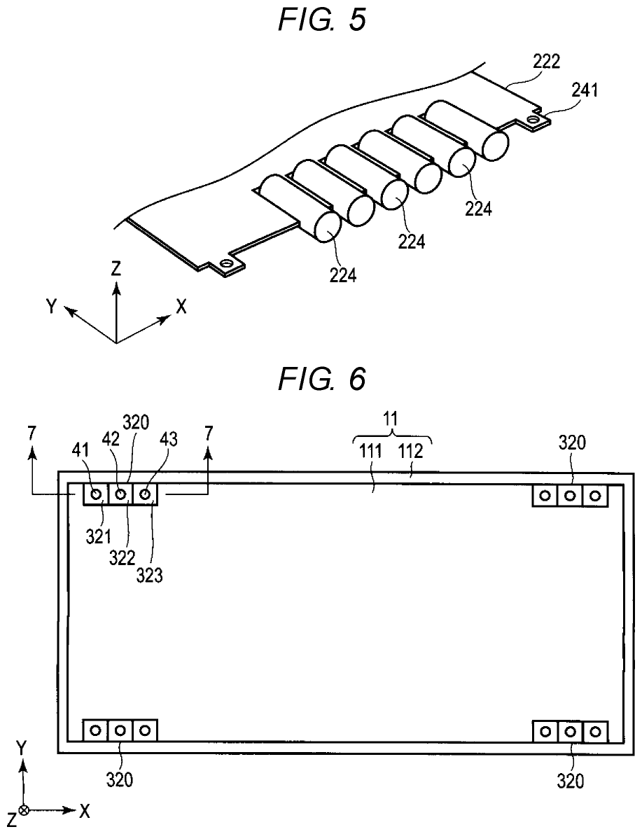

As shown in FIG. 5, a plurality of notches may be provided in one side of the second printed wiring board 220 along the X-axis and a plurality of capacitors 224 may be fitted to the plurality of notches, respectively as an alternative to the plurality of capacitors 224 on the lower surface F4 of the second printed wiring board 220. The number of notches is not necessarily two or more and may be one. A surface mount capacitor or a battery may be used as an alternative to the plurality of capacitors 224.

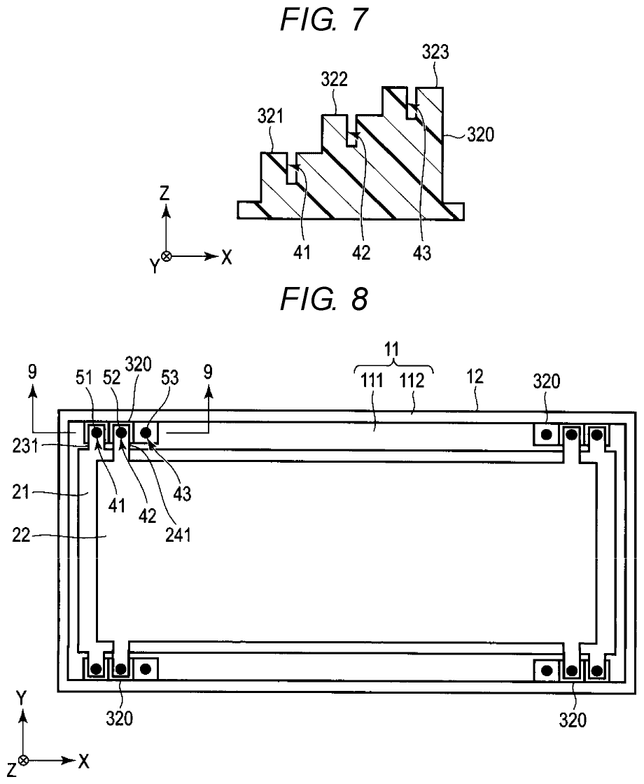

FIG. 6 is a plan view of the first base 111. FIG. 7 is a cross-sectional view taken along a line 7-7 of FIG. 6.

A plurality of stepped screw clamp portions 320 may be provided in four corners of the first base 111, respectively. FIG. 6 shows four screw clamp portions 320. The first PCB 21, the second PCB 22, and the cover 12 are screwed onto the screw clamp portions 320.

The upper left screw clamp portion 320 includes a first mounting face 321, a second mounting face 322, and a third mounting face 323. The first mounting face 321 is parallel to an X-Y plane specified by the three axes of the X, Y, and Z-axes. Likewise, the second mounting face 322 and the third mounting face 323 are parallel to the X-Y plane. The first mounting face 321 is disposed on an outermost side (side closest to the surface S1 of FIG. 2), the third mounting face 323 is disposed on an innermost side (side farthest to the surface S1 of FIG. 2), and the second mounting face 322 is disposed between the first mounting face 321 and the third mounting face 323.

Likewise, the lower left screw clamp portion 320 includes first to third mounting faces, the first mounting face is disposed on the outermost side (side closest to the surface S1 of FIG. 2), the third mounting face is disposed on the innermost side (side farthest to the surface S1 of FIG. 2), and the second mounting face is disposed between the first mounting face and the third mounting face.

Likewise, the upper right screw clamp portion 320 includes first to third mounting faces, the first mounting face is disposed on the outermost side (side closest to the surface S2 of FIG. 2), the third mounting face is disposed on the innermost side (side farthest to the surface S2 of FIG. 2), and the second mounting face is disposed between the first mounting face and the third mounting face.

Likewise, the lower right screw clamp portion 320 includes first to third mounting faces, the first mounting face is disposed on the outermost side (side closest to the surface S2 of FIG. 2), the third mounting face is disposed on the innermost side (side farthest to the surface S2 of FIG. 2), and the second mounting face is disposed between the first mounting face and the third mounting face.

As shown in FIG. 7, the second mounting face 322 is located upward of the first mounting face 321. It is defined that the relative positional relationship of elements arranged in the Z-axis direction is the vertically-structured relationship as described above, and that a direction of a Z-axis arrow is an upward direction. The third mounting face 323 is located upward of the second mounting face 322. A screw hole 41 is provided in the first mounting face 321. A screw hole 42 is provided in the second mounting face 322. A screw hole 43 is provided in the third mounting face 323.

FIG. 8 is a perspective view showing the base 11, the cover 12 (first cover 121), the first PCB 21, and the second PCB 22 from above the casing 10 of FIG. 1. FIG. 9 is a cross-sectional view taken along a line 9-9 of FIG. 8.

The protruding portions 231 of the first PCB 21 are screwed onto the screw clamp portions 320 using the screws 51. More specifically, the first PCB 21 is screwed onto the screw clamp portions 320 of the base 11 by fitting the screws 51 into the screw holes 41 via the through-holes (through-holes 232 in FIG. 3) of the protruding portions 231.

In a state of mounting the first PCB 21 to the base 11, the protruding portions 241 of the second PCB 22 are screwed onto the screw clamp portions 320 using the screws 52. More specifically, the second PCB 22 is screwed onto the screw clamp portions 320 of the base 11 by fitting the screws 52 into the screw holes 42 via the through-holes (through-holes 242 in FIG. 4) of the protruding portions 241.

In a state of mounting the first PCB 21 and the second PCB 22 to the base 11, the cover 12 is screwed onto the screw clamp portions 320 using screws 53. More specifically, the cover 12 is screwed onto the screw clamp portions 320 of the base 11 by fitting the screws 53 into the screw holes 43 via through-holes (not shown) of the cover 12.

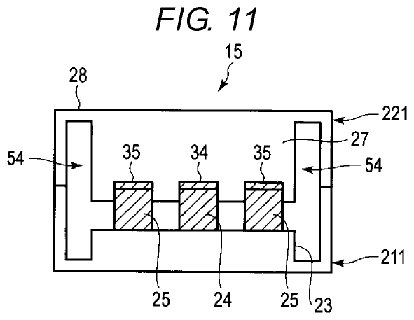

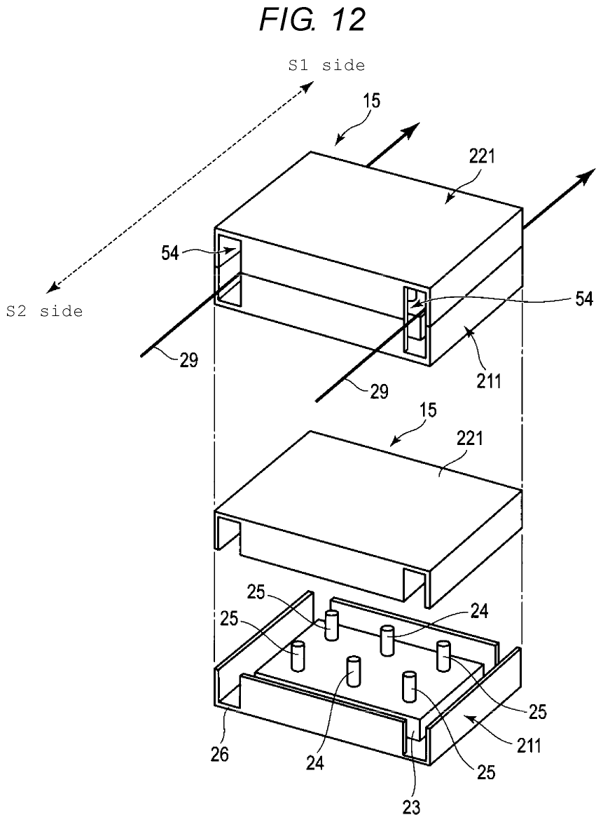

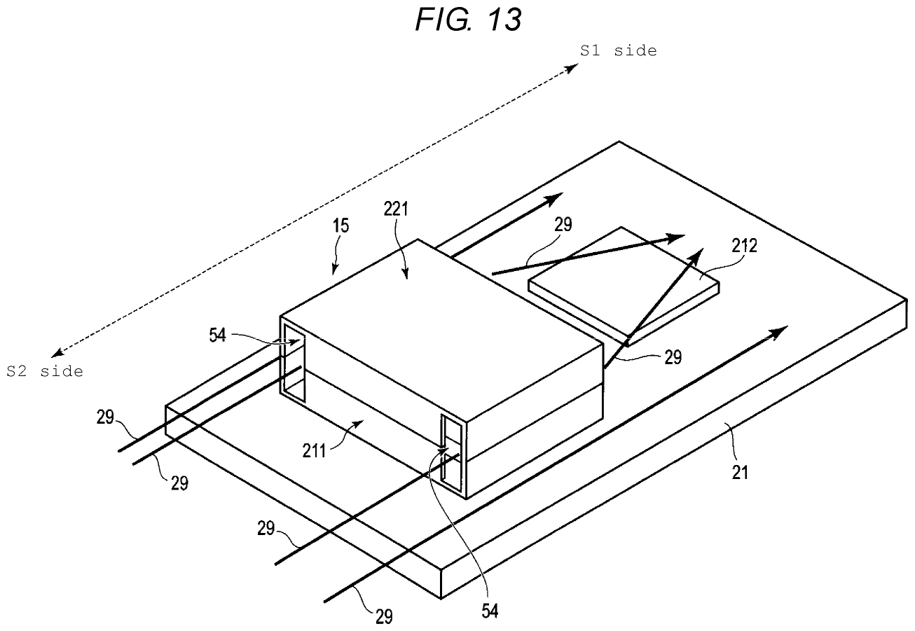

FIG. 10 is a plan view of the stacking connector 15 according to at least one embodiment. FIG. 11 is a cross-sectional view taken along a line 11-11 of FIG. 10. FIG. 12 is a perspective view of the stacking connector 15. An upper part of FIG. 12 shows the stacking connector 15 in a state in which the first connector 211 is connected to the second connector 221, while a lower part of FIG. 12 shows the stacking connector 15 in a state in which the first connector 211 is separated from the second connector 221.

As shown in FIGS. 11 and 12, the first connector 211 includes an upward raised pedestal 23 and pins (terminals) 24 and 25 provided on the pedestal 23. For example, each pin 24 is a signal pin and each pin 25 is a ground pin. The signal pin is a pin for transmitting the second control signal described above. The ground pin is connected to an interconnection at a ground potential (ground interconnection) of the first PCB 21.

Furthermore, as shown in FIG. 11, the second connector 221 includes a downward raised pedestal 27 and pins 34 and 35 provided on the pedestal 27. Each of the pins 34 and 35 is provided on a bottom or a side wall of a recess portion of the pedestal 27. When the pins 24 and 25 are inserted into these recess portions, the pins 24 and 34 are connected to each other and the pins 25 and 35 are connected to each other.

In the state in which the first connector 211 is connected to the second connector 221, the stacking connector 15 has two ventilation holes (through-holes) 54 through which fluid such as air (gas) or liquid can flow. These ventilation holes 54 are formed by a portion of the first connector 211 and a portion of the second connector 221.

The air is denoted by reference sign 29 in FIGS. 10 and 12. The air 29 flows in a −X direction. As shown in FIG. 10, the two ventilation holes 54 are provided on two end sides of the stacking connector 15 with respect to the Y-axis. Furthermore, as shown in FIG. 11, the pins 24 and 25 are disposed between the two ventilation holes 54.

FIG. 13 is a perspective view illustrating effects of the electronic apparatus according to at least one embodiment.

While the electronic apparatus 1 is operating, part of the air 29 generated using the cooling fan (not shown) or the like and flowing from the surface S2 of the cover 12 to the surface 51 of the cover 12 passes through the stacking connector 15 (connectors 211 and 221) via the ventilation holes 54. The NAND flash memory 212 is placed downstream of the air 29 passing through the stacking connector 15. When the passing air 29 flows on the NAND flash memory 212, the NAND flash memory 212 is cooled. As a result, an increase in a temperature of the NAND flash memory 212 is prevented.

A hole size, a hole shape, a hole disposition location, and the like specifying the ventilation holes 54, that is, specifications of the ventilation holes 54 are determined so that the air 29 passing through the stacking connector 15 flows on the NAND flash memory 212.

In a case of using a stacking connector without ventilation holes 54, it is impossible for the air 29 to pass through the stacking connector. Furthermore, since the air does not flow well between the first PCB 21 and the second PCB 22 shown in FIG. 2, it is impossible to cool the NAND flash memory 212 using the air 29. As a result, the temperature of the NAND flash memory 212 increases. Such a temperature increases incurs degradation of the NAND flash memory 212.

Examples of a solution to the degradation of the NAND flash memory 212 described above include the following technique or techniques. That is, the technique prevents an increase in the temperature of the NAND flash memory 212 by providing a temperature sensor near or in the NAND flash memory 212 and reducing an operating speed or a throughput of the NAND flash memory 212 when a temperature detected by this temperature sensor exceeds a constant value. This solution, however, incurs a performance degradation of the electronic apparatus.

According to at least one embodiment, by contrast, it is possible to prevent the increase in the temperature of the NAND flash memory 212 using the air 29. Due to this, it is unnecessary to reduce the operating speed or the throughput of the NAND flash memory 212 for preventing the temperature increase. According to at least one embodiment, therefore, it is possible to prevent an increase in the temperature of the NAND flash memory 212 without incurring the performance reduction of the electronic apparatus 1.

While a description of a cooling effect using FIG. 13 is related to the first PCB 21, a similar effect can be obtained in relation to the second PCB 22. In addition, the similar effect can be obtained for electronic components other than the NAND flash memory 212.

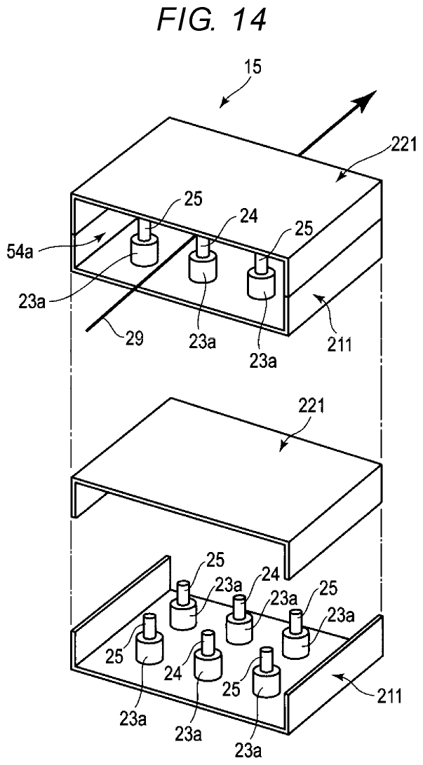

FIG. 14 is a perspective view illustrating a modification of the electronic apparatus according to at least one embodiment.

In this modification, the two ventilation holes 54 of the stacking connector 15 shown in FIG. 12 are changed to one ventilation hole 54a formed in such a manner as to join the two ventilation holes 54 together. In addition, in this modification, the one pedestal 23 shown in FIG. 12 is changed to a plurality of pedestals 23a. That is, the plurality of pins 24 and 25 are provided on the pedestals 23a, respectively. The plurality of pins 24 and 25 are disposed in the ventilation hole 54a.

According to this modification, it is possible for a larger amount of air 29 to flow on the NAND flash memory 212. Furthermore, a proportion of an area of surfaces (upper and side surfaces) of the NAND flash memory 212 exposed to the air (gas) can be increased. As a result, it is possible to prevent the increase in the temperature of the NAND flash memory 212 more effectively.

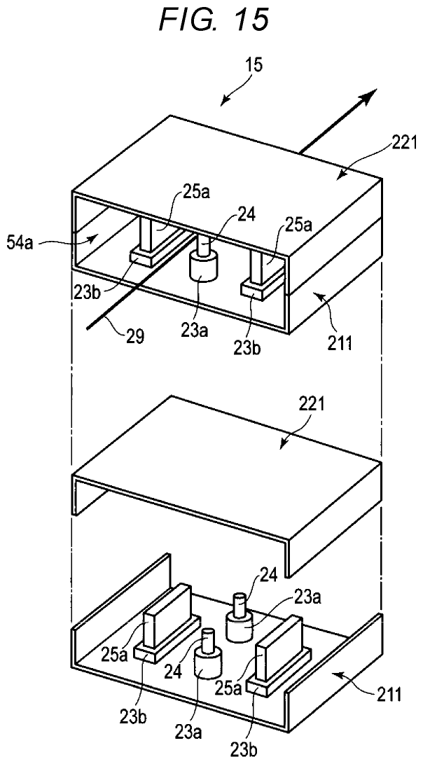

FIG. 15 is a perspective view illustrating another modification of the electronic apparatus according to at least one embodiment.

In this modification, each pair of pins (ground pins) 25 shown in FIG. 14 is changed to one plate-shaped ground pin 25a. Each pair of pedestals 23a is changed to one pedestal 23b, accordingly. The two pins 25a are arranged along an upstream side to a downstream side of the air 29.

According to this modification, the plate-shaped ground pins 25a can be used as a heat sink. The reason is as follows. When the temperature of the NAND flash memory 212 increases on the first PCB 21, heat is generated from the NAND flash memory 212. This generated heat propagates in the first printed wiring board 210 of the first PCB 21 itself or interconnections of the first PCB 21. This propagating heat propagates into the plate-shaped ground pins 25a. Owing to this, the plate-shaped ground pins 25a function as the heat sink that reduces a temperature of the first PCB 21. Likewise, when the temperature of each NAND flash memory 222 increases on the second PCB 22 and heat is generated from the NAND flash memory 222, this generated heat propagates into the second printed wiring board 220 of the second PCB 22 itself or interconnections of the second PCB 22 and the propagating heat propagates into the plate-shaped ground pins 25a. Therefore, the plate-shaped ground pins 25a function as a heat sink that reduces a temperature of the second PCB 22. As a result, it is possible to prevent an increase in the temperatures of the NAND flash memory 212 and 222 in the casing 10 more effectively.

While the ground pins 25a are connected to a ground interconnection of the first PCB 21 in at least one embodiment, it is also possible to adopt a configuration such that the ground pins 25a are connected to a ground interconnection of the second PCB 22. It is also possible to adopt a configuration such that the ground pins 25a are connected to a power supply interconnection of either the first PCB 21 or the second PCB 22.

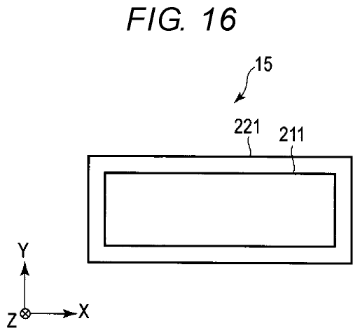

FIG. 16 is a plan view illustrating yet another modification of the electronic apparatus according to at least one embodiment.

In the stacking connector 15 in this modification, the first connector 211 and the second connector 221 are connected to each other in a state in which the first connector 211 is disposed inward of the second connector 221. Conversely, the second connector 221 may be disposed inward of the first connector 211.

In at least one embodiment, the electronic apparatus having a stacked structure in which the two PCBs are stacked in the Z-axis direction is described. However, the configurations according to at least one embodiment can be similarly applied to an electronic apparatus having a stacked structure in which three or more PCBs are stacked in the Z-axis direction.

In a case of, for example, a stacked structure in which a first PCB, a second PCB, and a third PCB are stacked in the Z-axis direction in this order, then the first PCB is connected to the second PCB by a first stacking connector, and the second PCB is connected to the third PCB by a second stacking connector.

Moreover, one of the male connector and the female connector of the first stacking connector is connected to one of a printed wiring board of the first PCB and a printed wiring board of the second PCB, and the other connector that is the male connector or the female connector of the first stacking connector is connected to the other printed wiring board of the first PCB or the second PCB.

Likewise, one of the male connector and the female connector of the second stacking connector is connected to one of the printed wiring board of the second PCB and a printed wiring board of the third PCB, and the other connector that is the male connector or the female connector of the second stacking connector is connected to the other printed wiring board of the second PCB or the third PCB.

While the example of the stacking connector including the one or two ventilation holes is described in the above embodiments, it is also possible to use a stacking connector including three or more ventilation holes.

Furthermore, while the SSD is described as the example of the electronic apparatus in the above embodiments, the electronic apparatus is not limited to the SSD. The electronic apparatus may have a structure in which boards such as a plurality of stacked PCBs are connected by a connector or connectors.

Part of or entirety of a generic concept, a medium concept, and specific concepts of at least one embodiment described above (the electronic apparatus and the stacking connector) and other embodiments that are not described above can be expressed by the following Notes 1 to 12 and freely selected combinations of Notes 1 to 20 (except for obviously contradictory combinations).

[Note 1] An electronic apparatus including:

a casing;

a first board that is provided in the casing and that has a first surface and a first connector provided on the first surface; and

a second board that is provided in the casing and that includes a second surface facing the first surface and a second connector provided on the second surface, wherein

the first connector and the second connector are connected to each other, and

the first connector and the second connector connected to each other include one or a plurality of ventilation passages.

[Note 2] The electronic apparatus according to Note 1, wherein

the first board further includes a third connector that can be electrically connected to an external apparatus.

[Note 3] The electronic apparatus according to Note 1 or 2, wherein

a first electronic component is provided on the first surface.

[Note 4] The electronic apparatus according to Note 3, wherein

a second electronic component is provided on the second surface.

[Note 5] The electronic apparatus according to Note 4, wherein

the first electronic component and the second electronic component are placed downstream of a fluid passing through the one or plurality of ventilation passages.

[Note 6] The electronic apparatus according to any one of Notes 1 to 5, wherein

one of the first connector and the second connector is a male connector of a stacking connector, and the other connector that is the first connector or the second connector is a female connector of the stacking connector.

[Note 7] The electronic apparatus according to any one of Notes 1 to 6, wherein

the one or plurality of ventilation passages are two ventilation holes.

[Note 8] The electronic apparatus according to Note 7, wherein

the male connector includes a first member and a first terminal provided on the first member, and

the first terminal is disposed between the two ventilation passages.

[Note 9] The electronic apparatus according to any one of Notes 1 to 6, wherein

the one or plurality of ventilation passages are one ventilation hole.

[Note 10] The electronic apparatus according to Note 6, wherein

the male connector includes a first member, a first terminal provided on the first member, a second member, and a second terminal provided on the second member, and

the first terminal and the second terminal are disposed in the one or plurality of ventilation passages.

[Note 11] The electronic apparatus according to Note 6, wherein

the male connector includes a first member, a first terminal provided on the first member, a second member, and a second terminal provided on the second member and larger in surface area than the first terminal, and

the first terminal and the second terminal are disposed in the one or plurality of ventilation passages.

[Note 12] The electronic apparatus according to Note 11, wherein

the second terminal is a plate-shaped terminal and connected to either a power supply interconnection or a ground interconnection of any one of the first board and the second board.

[Note 13] The electronic apparatus according to anyone of Notes 4 to 12, wherein

each of the first electronic component and the second electronic component is a nonvolatile memory.

[Note 14] The electronic apparatus according to anyone of Notes 1 to 13, wherein

the first board includes a first PCB (printed circuit board), and

the second board includes a second PCB.

[Note 15] A stacking connector including:

a first connector; and

a second connector, wherein

the first connector and the second connector can be connected to each other, and

the first connector and the second connector connected to each other include a through-hole.

[Note 16] The stacking connector according to Note 15, wherein

one of the first connector and the second connector of the stacking connector is a female connector, and the other connector that is the first connector or the second connector is a male connector.

[Note 17] The stacking connector according to Note 16, wherein

the male connector includes a first member, a first terminal provided on the first member, a second member, and a second terminal provided on the second member and larger in surface area than the first terminal.

[Note 18] The stacking connector according to Note 17, wherein

the second terminal is a plate-shaped terminal and connected to a ground interconnection of any one of the first board and the second board.

[Note 19] The stacking connector according to Note 16, wherein

the two through-holes are provided.

[Note 20] The stacking connector according to Note 19, wherein

the male connector includes a first member, a first terminal provided on the first member, and a second terminal provided on the first member.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An electronic apparatus comprising:
a casing;
a first board provided in the casing, the first board including a first surface and a first connector provided on the first surface; and
a second board provided in the casing, the second board including a second surface facing the first surface and a second connector provided on the second surface, wherein
the first connector and the second connector are connected to each other, and
the first connector and the second connector connected to each other include one or more through holes.

2. The electronic apparatus according to claim 1, wherein
the first board further includes a third connector configured to be electrically connected to an external apparatus.

3. The electronic apparatus according to claim 1, further comprising
a first electronic component and a second electronic component, the first electronic component and the second electronic component being placed downstream of a fluid passing through the one or more through holes.

4. The electronic apparatus according to claim 3, wherein
each of the first electronic component and the second electronic component is a nonvolatile memory.

5. The electronic apparatus according to claim 1, wherein
one of the first connector and the second connector is a male connector, and an other connector that is the first connector or the second connector is a female connector.

6. The electronic apparatus according to claim 5, wherein
the male connector and the female connector are part of a stacking connector, and
the male connector includes a first member and a first terminal, the first terminal provided on the first member.

7. The electronic apparatus according to claim 5, wherein
the male connector includes a first member, a first terminal provided on the first member, a second member, and a second terminal provided on the second member, and
the first terminal and the second terminal are disposed in the one or more through holes.

8. The electronic apparatus according to claim 5, wherein
the male connector includes a first member, a first terminal provided on the first member, a second member, and a second terminal provided on the second member, the second terminal being larger in surface area than the first terminal, and
the first terminal and the second terminal are disposed in the one or more through holes.

9. The electronic apparatus according to claim 8, wherein
the second terminal is a plate-shaped terminal, the second terminal being connected to either a power supply interconnection or a ground interconnection of either one of the first board or the second board.

10. The electronic apparatus according to claim 1, wherein
a first electronic component is placed on the first surface.

11. The electronic apparatus according to claim 10, wherein
a second electronic component is placed on the second surface.

12. The electronic apparatus according to claim 1, wherein
the one or more through holes are two through holes.

13. The electronic apparatus according to claim 12, wherein
the male connector includes a first member and a first terminal, the first terminal provided on the first member, and
the first terminal is disposed between the two through holes.

14. The electronic apparatus according to claim 1, wherein
the one or more through holes is a single through hole.

15. A stacking connector comprising:
a first connector; and
a second connector, wherein
the first connector and the second connector are configured to be connected to each other, and
the first connector and the second connector connected to each other include a through-hole.

16. The stacking connector according to claim 15, wherein
one of the first connector and the second connector of the stacking connector is a female connector, and the other connector out of the first connector and the second connector is a male connector.

17. The stacking connector according to claim 16, wherein
the male connector includes a first member, a first terminal provided on the first member, a second member, and a second terminal provided on the second member, the second terminal being larger in surface area than the first terminal.

18. The stacking connector according to claim 17, wherein
the second terminal is a plate-shaped terminal.

19. The stacking connector according to claim 16, wherein
two through-holes are provided.

20. The stacking connector according to claim 19, wherein
the male connector includes a first member, a first terminal provided on the first member, and a second terminal provided on the first member.
